(19) United States
(12) Patent Application Publication
(10) Pub. No.: US 2009/0322315 A1
(43) Pub. Date: Dec. 31, 2009

(54) LINEAR-MOVEMENT SENSOR IN AN EGR VALVE

(76) Inventor: Werner DENGLER, Nueziders (AT)

Correspondence Address: K.F. ROSS P.C., 5683 RIVERDALE AVENUE, SUITE 203 BOX 900, BRONX, NY, 10471-0900, US

(21) Appl. No.: 12/491,510

(22) Filed: Jun. 25, 2009

(30) Foreign Application Priority Data
Jun. 30, 2008 (DE) 102008030299.8

(51) Int. Cl. G01R 33/07; G01M 15/10

(52) U.S. Cl. 324/207.2; 73/114.74

(57) ABSTRACT

The invention concerns a device for determining the position of a linearly displaceable element (2) for controlling construction components, particularly for determining the position of a valve piston (1) of a bypass valve of an exhaust gas-recirculation system (also called EGR) where the linearly displaceable element (2) can be displaced in both directions of motion with the help of a device, preferably an electric motor with interconnection of a drive and an oscillating crank (3), or a pneumatic, hydraulic or electromagnetic actuator, whereby in accordance with the invention for the determination of the position of the linearly displaceable element (2), a magnet and a Hall sensor (5) or a rotation-sensitive magnetic sensor element are used.

The invention relates to a device for determining the position of a linearly displaceable element for controlling a part, particularly for the measurement of the position of the valve piston of a bypass valve of an exhaust gas-recirculation system (also called EGR), where the linearly displaceable element can be displaced by an actuator, preferably an electric motor by interconnection of a drive and an oscillating crank or a pneumatic, hydraulic or electromagnetic controller.

An exhaust-recirculation system of this type with bypass valve is generally known. The bypass valve controls the air and exhaust gas supply to the intake of an internal-combustion engine. The bypass valve has a piston that can be displaced by a push rod as a linearly displaceable element. The push rod in turn is controlled by an electric motor and a drive whose output has an oscillating crank connected with the push rod. Rotation sensors that measure the angle of the driven gear coupled with the oscillating crank determine the position of the linearly displaceable element.

This has the disadvantage that design and also installation tolerances of the drive and sensing system influence the quality of the measuring result or worsen such, as this is an indirect measurement.

It is the object of the invention to provide a device for determining the position of a linearly displaceable element and that also determines the exact position of the displaceable part so that tolerance errors can be eliminated. The device must be able to be calibrated and must also be insensitive to high temperatures and extreme differences in temperatures. Regardless of the type of bypass valve of an exhaust gas-recirculation system, the device is to be usable for any adjustment system, for example, of and engine, particularly in the exhaust system, as well as in the axle area and in the drive train of a motor vehicle.

The object of the invention is attained by determining of the position of the linearly displaceable element by use of a magnet and a dedicated Hall sensor. As a result of this design the position of the linearly displaceable element is measured directly and thus tolerances in the transmission or also tolerances relating to the installation of the device are avoided.

Advantageously, the magnet is directly fixed to the linearly displaceable element and the Hall sensor is fixed stationarily, preferably to a body part, in operational proximity to each other. As a result, the Hall sensor responds only to the magnetic field of the magnet.

Advantageously, the magnet is an axially polarized bar magnet. The bar magnet is designed and dimensioned in such a way, that its field lines run essentially parallel to the linearly displaceable element, preferably almost circular from north to south. As a result of this design and arrangement of the bar magnet directly on the linearly displaceable element, the Hall sensor captures the exact position of the linearly displaceable element so that mechanical tolerances in the drive, the oscillating crank, etc. are not in the tolerance chain. Axial magnetization is, however, not absolutely required when the magnet or the position generator, particularly the magnet target is designed in such a way that linear motion of the displaceable element also causes a change in an angular position of the field lines. This is the case, for example, in so-called E-Gas systems in vehicles.

In a further development of the invention, the bar magnet is designed and dimensioned in such a way that the field lines run essentially along the linearly displaceable element from north to south, preferably close to circular. This way, a particularly precise output signal of the sensor can be generated depending on the motion of the device being measured that is to be captured.

The drive of the part, particularly the valve piston, can thereby, as up to now, take place via the linearly displaceable element by a DC motor with planetary-gear train, the oscillating crank at the end of the planetary gear train transforming rotation into straight-line movement. The straight-line motion can also be generated directly by pneumatic, hydraulic or electromagnetic actuators.

In an additional embodiment of the invention the Hall sensor is designed as a so-called triaxial sensor or any other type of rotation-sensitive magnetic sensor. It is designed for sensing all three field components, Bx, By and Bz and for calculating the angles of the field lines to each other. In order to measure the position of the bar magnet it is sufficient, however, when two components are analyzed by the Hall sensor, e.g. By and Bz, or By and Bx, or Bx and Bz. This way, the following interrelationship results, for example:

Xₚₒₛ=M*arctan(By/Bx)

The formula in words: Xₚₒₛ (this means that the position of the valve piston or the linearly displaceable element, for example a push rod) is equal to the product of a value “m” and the arc tangent of the quotient of By and Bx. As a result of the calculation of the relationship of, for example, By and Bx, temperature and mechanical changes are minimized. The value “m” can be equal to 1, although it is also conceivable that this value is not equal to 1 (larger or smaller) and that it—as correction value or linearization value, for example—is adjusted for design or construction tolerances or also ensures that the output signal emitted by the sensor, that actually—based on the displacement of the device that is being measured (particularly the valve piston or the push rod) represent a rotating motion—are transformed into a linear signal sequence (increasing or decreasing initial output characteristics). This linearization value can be the same for the entire measurement path or also variable (for example exponential). Preferably, this value “m” is stored in memory and obtained from a table or a matrix, depending on the position of the valve piston or the linearly displaceable element, for example, the push rod.

In this way, the invention can be used for working temperature ranges of up to 160° C. and for large temperature differences. The precision of measurement is approximately 0.1 mm. Mechanical tolerances can be disregarded, as has already been explained, since measurement takes place directly at the part or its displacement element. The device can be calibrated and has long-term stability, because aging of the magnet does not influence the result.

For a further explanation of the invention, reference is made to the drawing in which an example of an embodiment of the invention is illustrated in simplified manner. Therein:

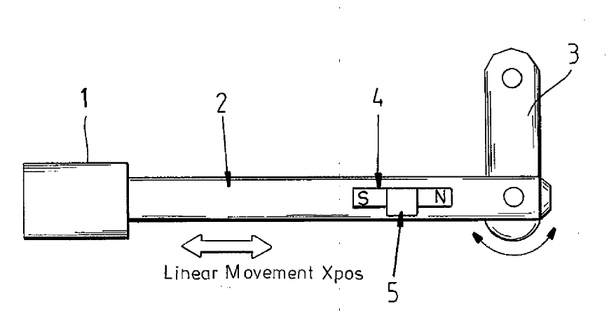

FIG. 1 is a lateral view of a device for determining the position of a valve piston of a bypass valve.

In FIG. 1, a valve piston of a bypass valve indicated at 1 and not shown in more detail is provided in a valve housing and controls the supply of air and exhaust to the intake system of a combustion engine. The valve piston 1 is connected with a linearly displaceable element 2, here a push rod. This linearly displaceable element 2 is made of a non-ferromagnetic material so that it does not disrupt the magnetism of a magnet. The free end of the linearly displaceable element 2 is connected by a linearly displaceable element, for example a pivot pin, to an oscillating crank 3. The oscillating crank 3 is a component of an unillustrated drive, particularly a planetary gear train that is controlled by an electric motor, particularly a DC motor.

The linearly displaceable element 2 carries a bar magnet labeled 4 that is axially magnetized. The bar magnet 4 has a dedicated Hall sensor 5 positioned in such a way that it can measure the field components of the bar magnet. The Hall sensor is stationarily mounted, in particular on a frame element. The Hall sensor 5 can, as explained in the general description, precisely determine the position of the bar magnet so that the position of the valve piston 1 or a different part, when the device is used in a different way, can be determined precisely and the output signal is available for control.

Legend

1 valve piston

2 linearly displaceable element

3 oscillating crank

4 bar magnet

5 Hall sensor

1. A device for determining the position of a linearly displaceable element for controlling a part, particularly for determining the position of a valve piston of a bypass valve of an exhaust-gas-recirculation system where the linearly displaceable element is displaceable in both directions of motion with the help of a device, preferably an electric motor with interconnected drive and an oscillating crank shaft or a pneumatic, hydraulic or electromagnetic actuator wherein for determining the position of the linearly displaceable element a magnet and a Hall sensor or a rotation-sensitive magnetic Hall sensor element are used.

2. The device according to claim 1 wherein the magnet is fixed on the linearly displaceable element and the Hall sensor is fixed, preferably on a frame part, in operating proximity to each other.

3. The device according to claim 1 wherein the magnet is an axially polarized bar magnet.

4. The device according to claim 1 wherein the bar magnet is designed and dimensioned in such a way that its field lines run essentially along the linearly displaceable element from north to south.

5. The device according to claim 1 wherein the Hall sensor is a triaxial sensor.

6. The device according to claim 1 wherein the Hall sensor is configured for sensing all three field components, Bx, By and Bz and for the calculation of the angles of the field lines relative to each other.
